(19) United States
(12) Patent Application Publication
(10) Pub. No.: US 2014/0036398 A1
(43) Pub. Date: Feb. 6, 2014

(54) ESD PROTECTION CIRCUIT WITH HIGH IMMUNITY TO VOLTAGE SLEW

(71) Applicant: Vladimir Kuznetsov, Allen, TX (US)

(72) Inventor: Vladimir Kuznetsov, Allen, TX (US)

(73) Assignee: TEXAS INSTRUMENTS INCORPORATED, Dallas, TX (US)

(21) Appl. No.: 13/567,239

(22) Filed: Aug. 6, 2012

(51) Int. Cl. H02H 9/04; H01L 21/02

(52) U.S. Cl. 361/56; 438/382; 257/E21.004

(57) ABSTRACT

A protection circuit (FIG. 2) for an integrated circuit is disclosed. The protection circuit comprises a protection transistor (MN0) having a current path coupled between a first terminal (VDD) and a second terminal (GND). A current mirror (MP1, MP0, MN2, MN1) has an output terminal coupled to a control terminal of the protection transistor. A delay circuit (R1, C0) is connected between the first and second terminals and has a delay output terminal connected to a first input terminal (MN1) of the current mirror.

### BACKGROUND OF THE INVENTION

Embodiments of the present embodiments relate to a metal oxide semiconductor (MOS) circuit for electrostatic discharge (ESD) protection. A preferred embodiment of the circuit is intended for use between power supply terminals such as VDD and GND (ground) or VSS, but the circuit may be used between any terminals of an integrated circuit.

Referring to FIG. 1, there is an ESD protection circuit of the prior art that is similar to those disclosed by Merrill in U.S. Pat. No. 5,239,440. The circuit includes a primary protection transistor MN0 having a current path coupled between power supply terminals VDD and GND. A complementary metal oxide semiconductor (CMOS) inverter formed by p-channel transistor MP0 and n-channel transistor MN1 has an output terminal connected to the gate of n-channel transistor MN0. An input terminal of the inverter is connected between resistor R1 and capacitor C0. In operation, no power is initially applied to the protection circuit and VDD, GND, and the gate of MNO are at the same potential. When a positive electrostatic discharge (ESD) stress voltage is applied to VDD with respect to GND, capacitor C0 initially holds the input voltage of the inverter near GND potential. Thus, MP0 is initially on and MN1 is initially off. In this mode, the gate and drain of MN0 are driven to a positive voltage to conduct ESD stress current from VDD to GND. Resistor R1 and capacitor C0 are typically designed to maintain a positive voltage on the gate of MN0 until the ESD stress voltage is discharged. For human body model (HBM) ESD stress this may be approximately 1 microsecond. After this time, resistor R1 charges capacitor C0 to a voltage sufficient to turn on MN1 and turn off MP0. In this mode, the output of the inverter and the gate of MN0 are driven to GND, and MN0 is off.

One of the problems with the circuit of FIG. 1 is that n-channel transistor MN0 may be activated by a wide range of rise times for positive voltage applied to VDD. This may be acceptable for several forms of ESD stress such as HBM, machine model (MM), or charged device model (CDM) tests as are known in the art. A problem arises, however, when the protection circuit of FIG. 1 is subjected to a hot-plug or hot-socket insertion test. In this test, an integrated circuit or printed circuit board is inserted into a socket with power already applied to VDD and GND power supply terminals. Thus, rise time of voltage at the gate of MN0 is often rapid and unpredictable. In some cases, the resulting high current flow between VDD and GND may be sufficient to damage MN0 or cause other circuit problems. Therefore, there is a need to provide a protection circuit that is responsive to ESD stress but immune to high voltage slew (dVDD/dt) during hot-plug or hot-socket insertion.

### BRIEF SUMMARY OF THE INVENTION

In a preferred embodiment of the present invention, a circuit for protecting an integrated circuit is disclosed. The circuit includes a protection transistor having a current path coupled between a first and a second terminal. A control terminal of the protection transistor is coupled to an output terminal of a current mirror. A first input terminal of the current mirror is coupled an output terminal of a delay circuit.

### BRIEF DESCRIPTION OF THE SEVERAL VIEWS OF THE DRAWING

FIG. 1 is a schematic diagram of an electrostatic discharge (ESD) protection circuit of the prior art;

FIG. 2 is a schematic diagram of an electrostatic discharge (ESD) protection circuit of the present invention;

FIG. 3 is a cross-sectional view showing operation of n-channel transistor MN0;

FIG. 4 is a simulation showing current through MN0 as a function of VDD rise time for the circuits of FIGS. 1 and 2;

FIG. 5 is a simulation showing gate voltage of MN0 as a function of HBM stress voltage;

FIG. 6 is a simulation showing the clamping of MN0 during metal oxide semiconductor (MOS) conduction as a function of HBM stress voltage;

FIG. 7 is a simulation showing shut off time for the protection circuit of FIG. 2 as a function of HBM stress voltage;

FIG. 8 is a diagram showing measured transmission line pulse (TLP) current-voltage characteristics and simulated current-voltage characteristics of the circuits of FIGS. 1 and 2; and

FIG. 9 is a diagram showing measured transmission line pulse (TLP) current-time characteristics of the circuits of FIGS. 1 and 2.

### DETAILED DESCRIPTION OF THE INVENTION

The preferred embodiments of the present invention provide significant advantages over electrostatic discharge (ESD) protection circuits of the prior art as will become evident from the following detailed description.

Referring to FIG. 2, there is a schematic diagram of an electrostatic discharge (ESD) protection circuit of the present invention. The circuit includes protection transistor MN0 having a current path coupled between VDD and GND and having a control terminal coupled to GND by resistor R0. A current mirror is including p-channel transistors MP0 and MP1 and n-channel transistors MN1 and MN2 is also coupled between VDD and GND. An output terminal of the current mirror is connected to the control terminals of MN0 and MN2. A delay circuit formed by series-connected resistor R1 and capacitor C0 has an output terminal connected to an input terminal of the current mirror at the gate of n-channel transistor MN1 and determines when the current mirror will turn off. An activation circuit formed by a parasitic capacitance between the gate and drain of MN0 and resistor R0 determines when MN0 and the current mirror will turn on. Resistor R0 is selected such that a worst case change of VDD in time during a hot-socket insertion will not activate MN0.

Referring now to FIG. 3, there is cross-sectional view showing operation of n-channel protection transistor MN0. Here, MN0 is shown as a single transistor to illustrate the principle of operation. For practical applications, however, MN0 preferably includes multiple transistors connected in parallel. The circuit includes drain terminal 108, source terminal 106, and gate terminal 102. A parasitic NPN bipolar transistor 114 is formed in parallel with transistor MN0. The base of the NPN bipolar transistor 114 is preferably connected to GND through substrate resistance 116. Control circuit 100 operates to control the voltage VG on gate terminal 102 in response to coupling from gate-to-drain parasitic capacitor 104. During normal circuit operation or during a hot-socket insertion, voltage coupled through parasitic capacitor 104 across resistor R0 (in control circuit 100) is insufficient to turn on MN0. During an ESD event, however, the rate of change of VDD with respect to time (dVDD/dt) increases voltage VG above a threshold voltage of MN0. This increase in voltage VG forms an inversion layer 112 in the channel region of MN0 under gate 102. In this mode, MN0 operates in saturation and generates electron-hole pairs in pinch-off region 110. The electrons are swept into drain region 108, and the holes serve to forward bias the base of NPN bipolar transistor 114. Therefore, both MOS transistor MN0 and bipolar NPN transistor 114 operate in parallel to conduct ESD current from VDD to GND. Moreover, this increase in gate voltage VG and saturation of MN0 is necessary to turn on all parallel transistors of MN0 during an ESD event. Otherwise only some of the parallel transistors would turn and current hog, thereby preventing the remaining transistors of MN0 from turning on and reducing the protection level of the circuit.

Returning now to FIG. 2, no power is initially applied to the protection circuit and VDD, GND, and the gate of MN0 are at the same potential. When a positive electrostatic discharge (ESD) stress voltage is applied to VDD with respect to GND, capacitor C0 initially holds the input voltage of the current mirror at the gate of MN1 near GND potential. The parasitic capacitance 104 (FIG. 3) between the gate and drain of MN0 together with R0 function as an activation circuit to initially turn on n-channel transistors MN0 and MN2. MN2 drives the common gate terminal of MP0 and MP1 low to turn on the current mirror. In this mode, p-channel transistor MP0 provides sufficient current through resistor R0 to keep MN0 on, thereby conducting ESD current from VDD to GND. The ESD voltage is reduced until the total current through MP0, MP1, and MN0 reaches a safe level of approximately 5 mA. At this level, the current through resistor R0 is insufficient to maintain an n-channel threshold voltage and MN0 turns off. Alternatively, resistor R1 may charge capacitor C0 to a voltage greater than an n-channel threshold voltage at the output of the delay circuit, thereby turning on MN1. In this mode, MN1 overrides MP0 and drives the gates of MN2 and MN0 low, thereby turning off MN0 and the current mirror.

The present invention is highly advantageous for several reasons. First, protection transistor MN0 does not turn on during hot-socket insertion tests or during any specified change of VDD with respect to time. Second, initial conduction of protection transistor MN0 is determined by parasitic capacitor 104 and resistor R0. Duration of MN0 conduction, however, is determined by the delay circuit formed by resistor R1 and capacitor C0. Thus, component values are selected independently. Third, the high impedance of current mirror transistors isolates any change of gate voltage VG at the gate of MN0 from the delay circuit. Finally, transistor MN0 will advantageously turn off after a timed delay determined by the delay circuit or when the ESD current is sufficiently reduced.

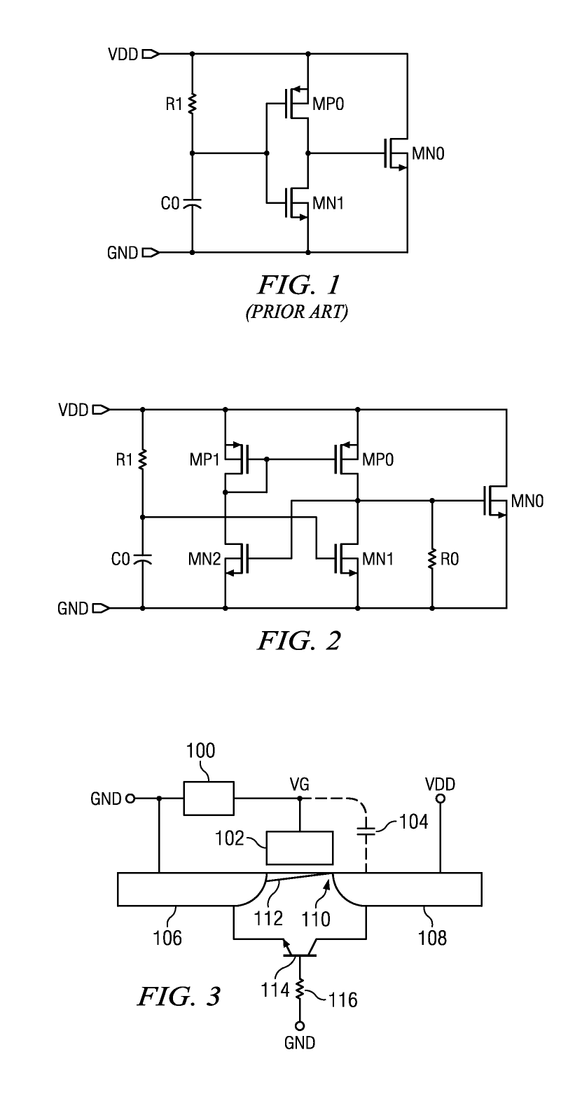

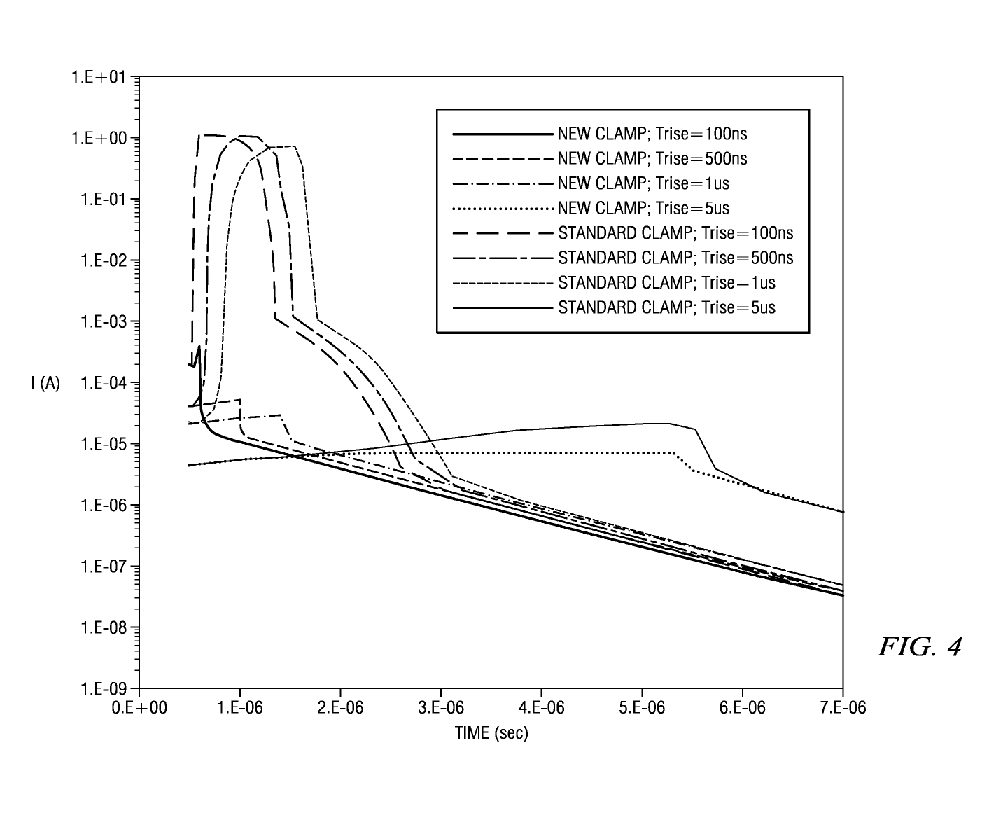

Turning now to FIG. 4, there is a simulation showing current through MN0 as a function of VDD rise time for the circuits of FIGS. 1 and 2. Here and in the following simulations, transistor sizes are the same for FIGS. 1 and 2 for the purpose of comparison. For example, R0=1.5 kΩ, MP0=200 μm, MP1=20 μm, MN1=20 μm, MN2=15 μm, MN0=7000 μm, and the time constant of R1 and C0 is 0.8 μs. All transistor channel lengths are 0.18 μm. Actual sizes, however, will vary for different processes. The first five curves show the current through MN0 for the new clamp of FIG. 2 remains below 0.1 mA for VDD rise times of 100 ns through 5.0 μs at a 3.3 V amplitude. This represents a wide range of VDD rates of change as might be found with hot-socket insertion of VDD glitches during normal circuit operation. In each case, however, the MN0 transistor of the new clamp maintains a consistently low current level. By way of comparison, the standard clamp circuit of FIG. 1 shows a peak current of approximately 1.0 A for VDD rise times of 100 ns through 1.0 μs at a 3.3 V amplitude. As previously discussed, this level of current may be sufficient to damage MN0 or cause other circuit problems.

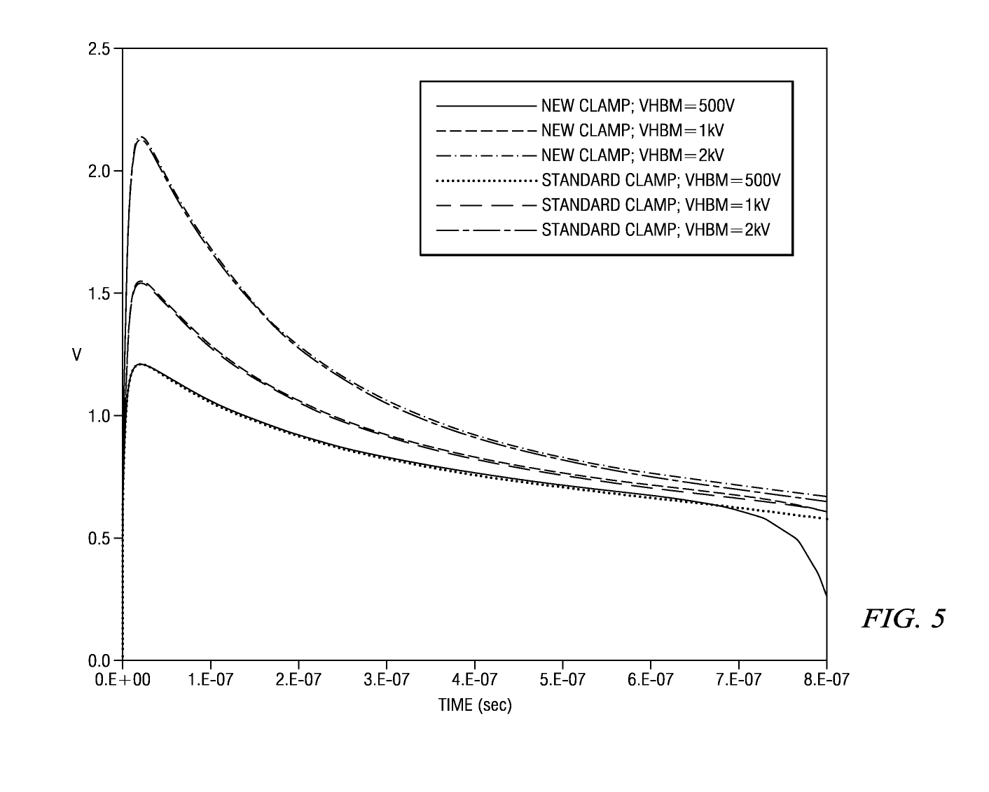

Referring now to FIG. 5, there is a simulation showing gate voltage of MN0 as a function of human body model (HBM) stress voltage for stress voltages from 500 V to 2.0 kV. Both clamp circuits of FIGS. 1 and 2 have approximately the same MN0 gate voltage for the first five time constants (750 ns) of HBM stress. Thus, both clamp circuits of FIGS. 1 and 2 should perform approximately the same under ESD stress.

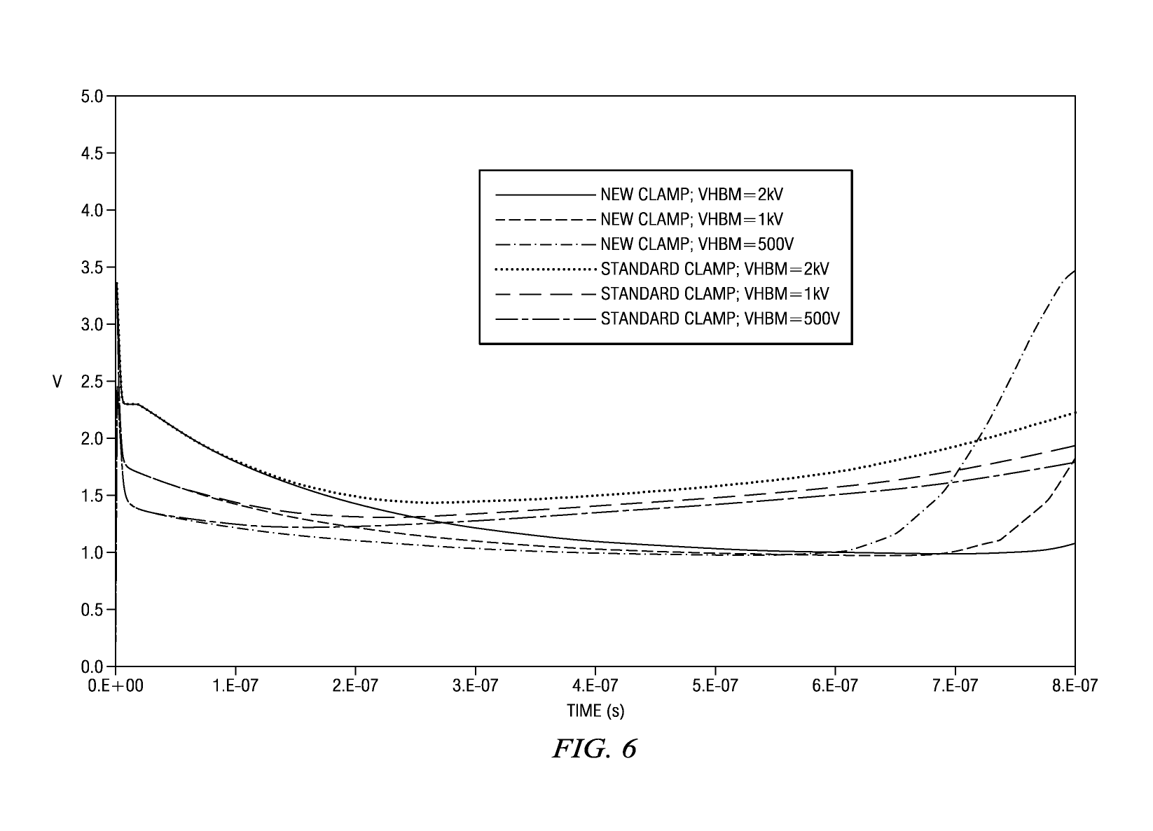

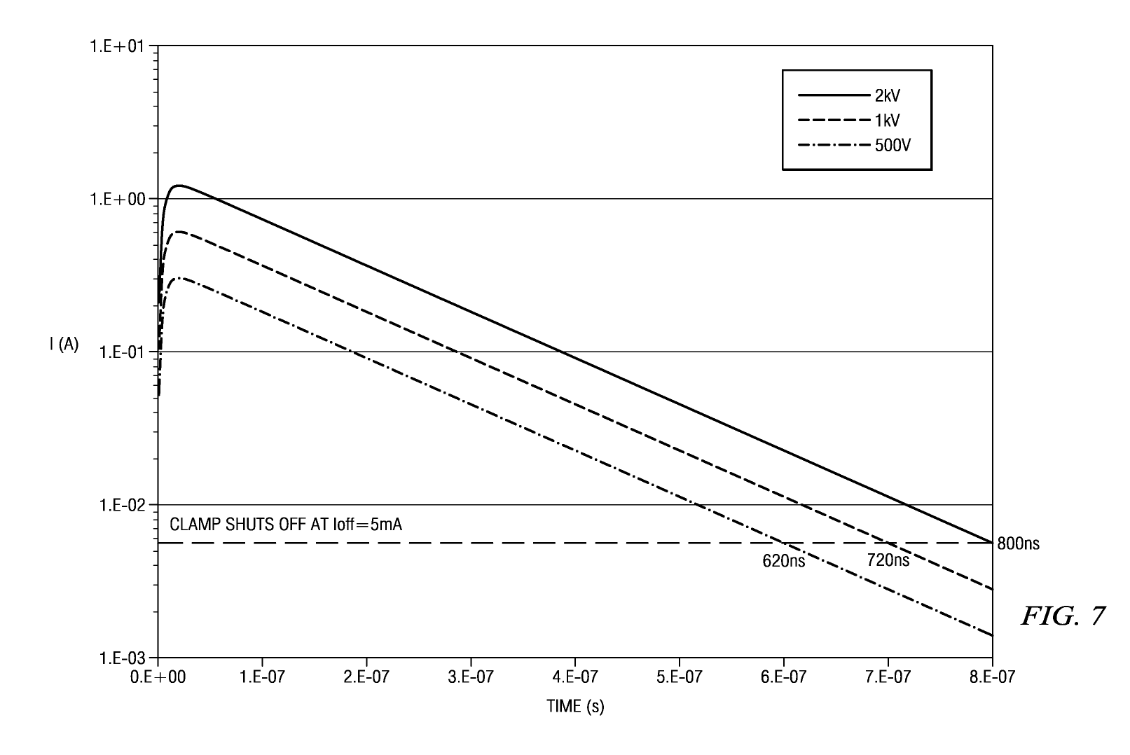

Referring next to FIG. 6, there is a simulation showing the clamping of MN0 during metal oxide semiconductor (MOS) conduction as a function of HBM stress voltage for stress voltages from 500 V to 2.0 kV. Here, the new clamp circuit of FIG. 2 maintains a voltage across MN0 at or below the voltage of the standard clamp (FIG. 1) of the prior art for the first four time constants of HBM stress (600 ns). After this time, the ESD stress current has reached a safe level of approximately 5 mA and MN0 turns off. This is illustrated at the simulation of FIG. 7. Here, the new clamp of FIG. 2 reaches a safe current level of approximately 5 mA (Ioff) at 620 ns, 720 ns, and 800 ns for HBM stress voltages of 500 V, 1.0 kV, and 2.0 kV, respectively.

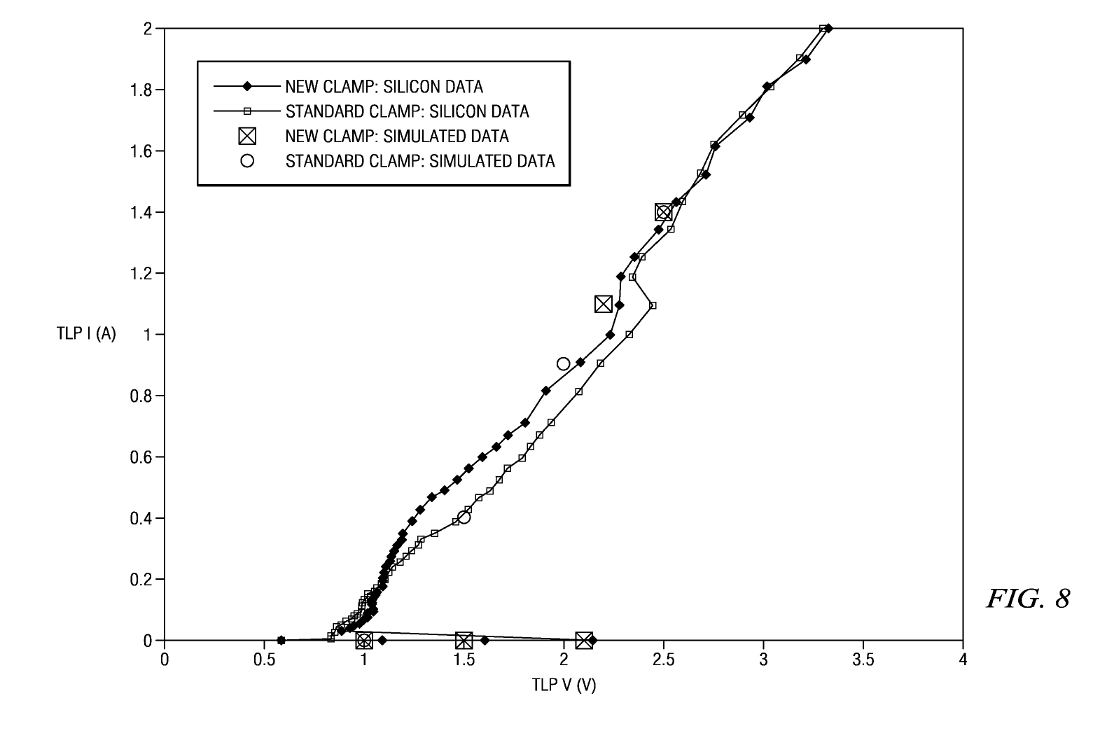

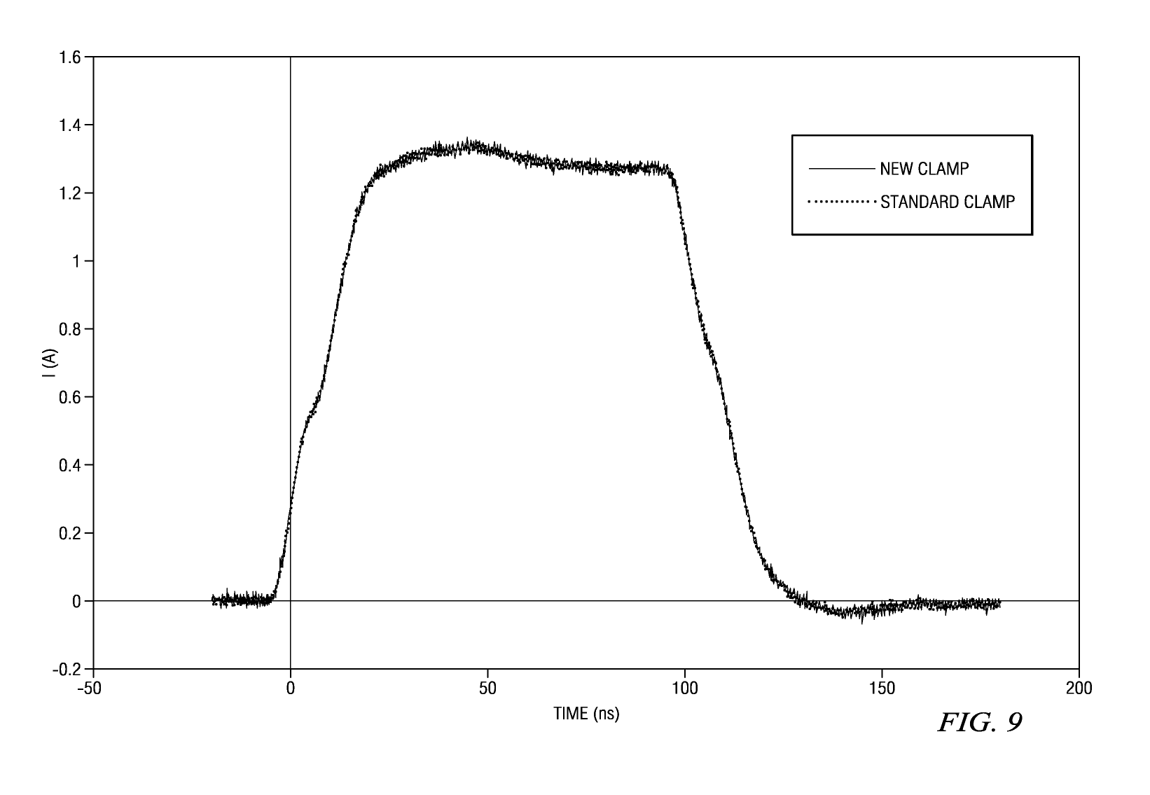

Referring now to FIG. 8, there is a diagram showing measured transmission line pulse (TLP) current-voltage characteristics and simulated current-voltage characteristics of the circuits of FIGS. 1 and 2. The horizontal axis indicates the initial voltage of the transmission line and the vertical axis indicates the current through MN0 at that voltage. Here, both TLP stress and simulations show comparable performance under high current stress for the new clamp circuit (FIG. 2) and the standard clamp (FIG. 1) of the prior art. FIG. 9 is a TLP waveform showing current along the vertical axis as a function of time for both the new clamp circuit (FIG. 2) and the standard clamp (FIG. 1). The time of the TLP waveform is determined by the length of the transmission line or coaxial cable. This shows that both circuits of FIGS. 1 and 2 perform equally well under high current stress comparable to ESD stress levels.

Still further, while numerous examples have thus been provided, one skilled in the art should recognize that various modifications, substitutions, or alterations may be made to the described embodiments while still falling within the inventive scope as defined by the following claims. For example, although protection transistor MN0 is an n-channel MOS transistor in one embodiment of the present invention, one of ordinary skill in the art having access to the instant specification will understand that the protection transistor might also be only an NPN bipolar transistor or one bipolar transistor of a semiconductor controlled rectifier (SCR). Other combinations will be readily apparent to one of ordinary skill in the art having access to the instant specification.

What is claimed is:

1. A protection circuit, comprising:
a first terminal;
a second terminal;
a protection transistor having a control terminal and having a current path coupled between the first and second terminals;
a current mirror having an output terminal coupled to the control terminal and having an input terminal; and
a delay circuit connected between the first and second terminals and having a delay output terminal connected to the input terminal.

2. A protection circuit as in claim 1, wherein the protection transistor is an n-channel transistor.

3. A protection circuit as in claim 1, wherein the protection transistor is a bipolar transistor.

4. A protection circuit as in claim 1, wherein the current mirror comprises:
a first p-channel transistor having a source connected to the first terminal and having a gate connected to a drain terminal; and
a second p-channel transistor having a source connected to the first terminal, having a gate connected to the gate of the first p-channel transistor, and having a drain connected to the control terminal.

5. A protection circuit as in claim 4, wherein the current mirror comprises:
a first n-channel transistor having a drain connected to the drain of the first p-channel transistor and having a gate connected to the control terminal; and
a second n-channel transistor having a drain connected to the drain of the second p-channel transistor and having a gate connected to the input terminal

6. A protection circuit as in claim 1, wherein the delay circuit comprises:
a resistor connected between the first terminal and the delay output terminal; and
a capacitor connected between the delay output terminal and the second terminal.

7. A protection circuit as in claim 1, wherein the delay circuit comprises:
a delay transistor having a current path connected between the first terminal and the delay output terminal; and
a capacitor connected between the delay output terminal and the second terminal.

8. A protection circuit as in claim 1, comprising a resistor connected between the control terminal and the second terminal

9. A method of protecting an integrated circuit, comprising:
forming a protection transistor having a control terminal and having a current path coupled in parallel with the integrated circuit;
activating the protection transistor in response to a voltage across the current path of the first protection transistor; and
maintaining the active state of the protection transistor in response to a delay circuit.

10. A method as in claim 9, wherein the step of forming a protection transistor comprises forming an n-channel transistor.

11. A method as in claim 9, wherein the step of forming a protection transistor comprises forming an NPN bipolar transistor.

12. A method as in claim 9, comprising activating the protection transistor in response to a capacitor connected in series with a resistor and in parallel with the protection transistor current path, wherein a common terminal of the resistor and capacitor is connected to the control terminal.

13. A method as in claim 9, wherein the step of maintaining the active state comprises applying current from a current source to the control terminal of the protection transistor.

14. A method as in claim 13, wherein the current source is a current mirror.

15. A method as in claim 9, wherein the delay circuit is formed by a resistor connected in series with a capacitor.

16. A protection circuit, comprising:
a first terminal;
a second terminal;
a protection transistor having a control terminal and having a current path coupled between the first and second terminals;
an activation circuit arranged to activate the protection transistor in response to a voltage between the first and second terminals; and
a delay circuit arranged to maintain the active state of the protection transistor for a predetermined time.

17. A protection circuit as in claim 16, comprising a current mirror having an output terminal coupled to the control terminal and having an input terminal coupled to the delay circuit.

18. A protection circuit as in claim 16, wherein the protection transistor is an n-channel transistor.

19. A protection circuit as in claim 16, wherein the delay circuit comprises:
a resistor connected between the first terminal and a delay output terminal; and
a capacitor connected between the delay output terminal and the second terminal.

20. A protection circuit as in claim 16, wherein the delay circuit comprises:
a delay transistor having a current path connected between the first terminal and a delay output terminal; and
a capacitor connected between the delay output terminal and the second terminal.
